(19) United States
(12) Patent Application Publication
(10) Pub. No.: US 2025/0202476 A1
(43) Pub. Date: Jun. 19, 2025

(54) WAKE UP CIRCUIT

(71) Applicant: N.S. International, Ltd., Troy, MI (US)

(72) Inventors: Xinqiao Wang, Troy, MI (US); Cesar Rivas, Troy, MI (US); Daniel Sanchez, Troy, MI (US); Slavko Bogoevski, Troy, MI (US)

(21) Appl. No.: 18/538,985

(22) Filed: Dec. 13, 2023

(51) Int. Cl. H03K 17/30; G06F 1/3234; H03K 17/687

(52) U.S. Cl. CPC H03K 17/302; G06F 1/3243; H03K 17/687

(57) ABSTRACT

An apparatus for waking up a microcontroller based on an analog signal superimposed on a low voltage differential signal line in an automobile. The apparatus is realized using a pair of FETs and switches arranged to act as a latching circuit when a sufficient analog signal is detected and remains present even when the signal drops below a wake up threshold. The gate voltage threshold of the pair of FETs may be selected to control the voltage where latching does and does not occur. The apparatus also triggers a sleep cycle in the microcontroller if the signal drops below a threshold voltage. The microcontroller may be programmed to perform a controlled shutdown and terminate its power via the apparatus when finished.

### FIELD OF THE INVENTION

The present invention generally relates an apparatus for waking up a subsystem including a processor. More specifically, the present invention relates to using a wake up signal in an automobile to activate a subsystem and to put the same subsystem to sleep in a controlled power down procedure after the wake up signal is removed and a sleep signal is received.

### BACKGROUND OF THE INVENTION

Electrical systems have been told to “wake up” for years using dedicated signal lines to activate or power up a processor. Typically, waking up a processor requires activation of a power source to operate the processor and triggering a wake up cycle, or the processor always remains on standby waiting for an activation signal. Keeping a processor on standby requires a continuous outlay of power, which can be a problem for systems that have limited access to power or rely on batteries, rather than the electric grid. Still other circuits used for waking up a processor require complex logic gates arrangements that require additional power, additional cost, and increase the probability of failure.

Thus, one shortcoming of existing wake up circuits is the requirement of a dedicated signal line. Another shortcoming is a continuous power drain to maintain the processor in hot standby. Another shortcoming is the complex and costly arrangement of circuit elements and logic circuits to realize the wake up circuit.

Therefore, there exists a heretofore unmet need for a wake up apparatus that does not require a dedicated signal line, does not require the processor to be in hot standby waiting to receive a wake up signal, is able to detect a wake-up signal communicated as an analog voltage which reflects the system battery level, and realized as a simple and cost effective circuit.

### SUMMARY OF THE DISCLOSURE

The present invention is an apparatus for waking up a subsystem in an automobile using an analog signal. Specifically, the apparatus is configured to receive an analog signal activating a power source to a processor, such as a microcontroller, without the processor being powered in a standby mode. For battery powered systems, the subsystem may go to sleep when battery drops below a certain level and wake up when battery voltage level is above the threshold if the system is enabled.

One embodiment of the present disclosure is an apparatus that includes: an input line configured to receive a signal from a low voltage differential signal line; a first field effect transistor (FET) with a gate in electrical communication with the input line; a first switch configured to be controlled by a source of the first FET; a power input in electrical communication with a first side of the first switch; a power output in electrical communication with a second side of the first switch; a second switch with a first side in electrical communication with the source of the first FET and configured to receive a hold control signal; and a second FET with a gate in electrical communication with the input line and a drain in electrical communication with a pullup resistor and a sleep signal output. The first switch may include a MOSFET and the second switch may include a BJT. The apparatus may also include a power source in electrical communication with the power input. The apparatus may also include a microcontroller configured to (1) receive power through the power output, (2) output the hold control signal, and (3) receive a sleep signal from the sleep signal output.

Another embodiment of the present disclosure includes a method of waking up a microcontroller in an apparatus including: an input line configured to receive a signal from a low voltage differential signal line; a first field effect transistor (FET) with a gate in electrical communication with the input line; a first switch configured to be controlled by a drain of the first FET; a power input in electrical communication with a first side of the first switch; a power source in electrical communication with the power input; a power output in electrical communication with a second side of the first switch; a second switch with a first side in electrical communication with the drain of the first FET and configured to receive a hold control signal; a second FET with a gate in electrical communication with the input line and a drain in electrical communication with a pullup resistor and a sleep signal output; and a microcontroller configured to (1) receive power through the power output, (2) output the hold control signal, and (3) receive a sleep signal from the sleep signal output; and including the steps of: extracting an analog signal from the low voltage differential signal line; energizing the gate of the first FET to connect the power input to the power output through the first switch; energizing the microcontroller using power from the power source communicated through the first switch; and receiving a hold signal from the microcontroller to the first switch to maintain the first switch connecting the power input to the power output. The first FET and the second FET may be selected with a gate voltage threshold in the range 1.26 volts to 3.17 volts.

Another embodiment of the present disclosure includes a method of shutting down a microcontroller in an apparatus including: an input line configured to receive a signal from a low voltage differential signal line; a first field effect transistor (FET) with a gate in electrical communication with the input line; a first switch configured to be controlled by a drain of the first FET; a power input in electrical communication with a first side of the first switch; a power source in electrical communication with the power input; a power output in electrical communication with a second side of the first switch; a second switch with a first side in electrical communication with the drain of the first FET and configured to receive a hold control signal; a second FET with a gate in electrical communication with the input line and a drain in in electrical communication with a pullup resistor and a sleep signal output; and a microcontroller configured to (1) receive power through the power output, (2) output the hold control signal, and (3) receive a sleep signal from the sleep signal output; and including the steps of: extracting an analog signal from the low voltage differential single line; deenergizing the gate of the second FET to energize the sleep signal output; running a power off sequence on the microcontroller; and initiating a signal to open the second switch which opens the first switch and terminates power to the microcontroller.

Examples of the more important features of the disclosure have been summarized rather broadly in order that the detailed description thereof that follows may be better understood and in order that the contributions they represent to the art may be appreciated. There are, of course, additional features of the disclosure that will be described hereinafter and which will form the subject of the claims appended hereto.

### BRIEF DESCRIPTION OF THE DRAWINGS

The organization and manner of the structure and operation of the invention, together with further objects and advantages thereof, may best be understood by reference to the following description taken in connection with the accompanying drawings wherein like reference numerals identify like elements in which:

FIG. 1 is a diagram of a wake up apparatus according to one embodiment of the present disclosure; and

FIG. 2 is a diagram of a system using the wake up apparatus according to one embodiment of the present disclosure.

### DETAILED DESCRIPTION OF THE DISCLOSURE

While this invention may be susceptible to embodiment in different forms, specific embodiments are shown in the drawings and will be described herein in detail with the understanding that the present disclosure is to be considered an exemplification of the principles of the invention and is not intended to limit the invention to that as illustrated.

A wake up/sleep signal may be used to turn on one or more vehicle subsystems. Optionally, the wake up/sleep system may also be used to reflect vehicle battery level. If a vehicle battery level drops below a predetermined threshold, a wake up/sleep system may be used to interpret the voltage drop as a sleep signal and activate a controlled shutdown or sleep cycle in order to protect the vehicle components from failure associated with low or no voltage conditions caused by a failing or failed battery. A sleep cycle can be a controlled operation where systems are shutdown properly, data is stored in memory, and the systems are reset to a condition where they can be readily awakened once power to the system is restored.

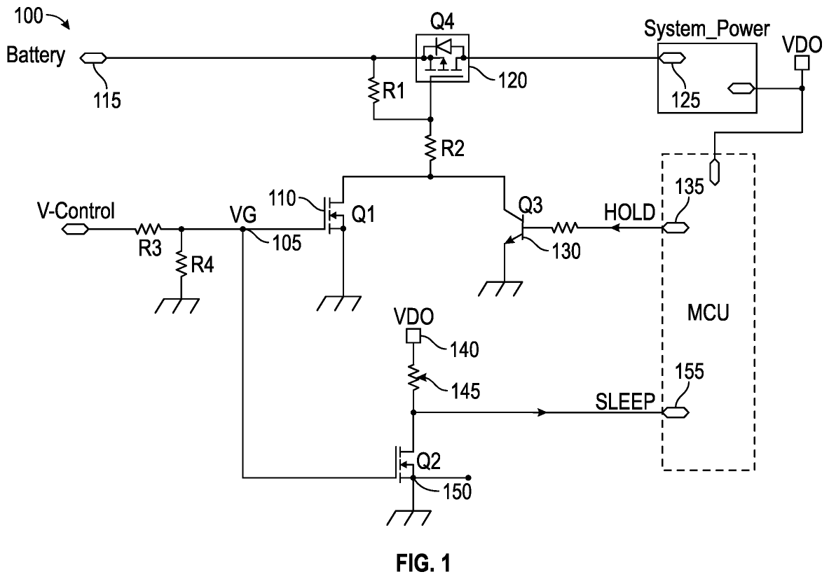

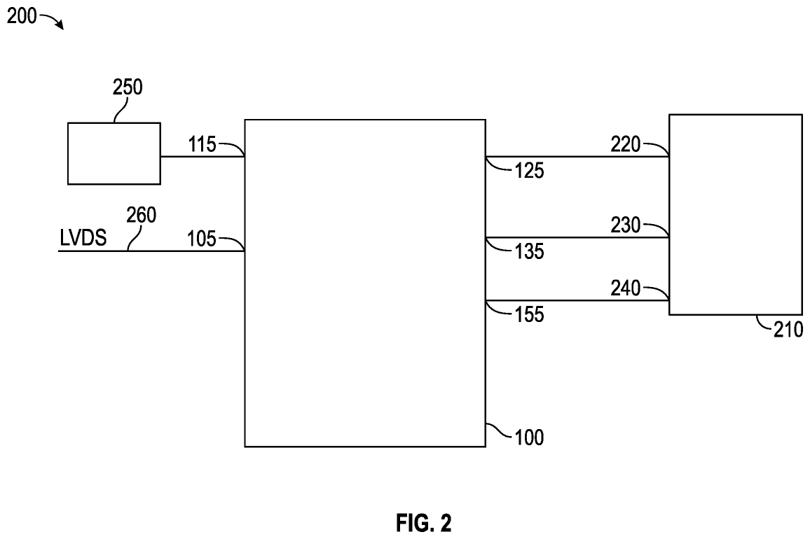

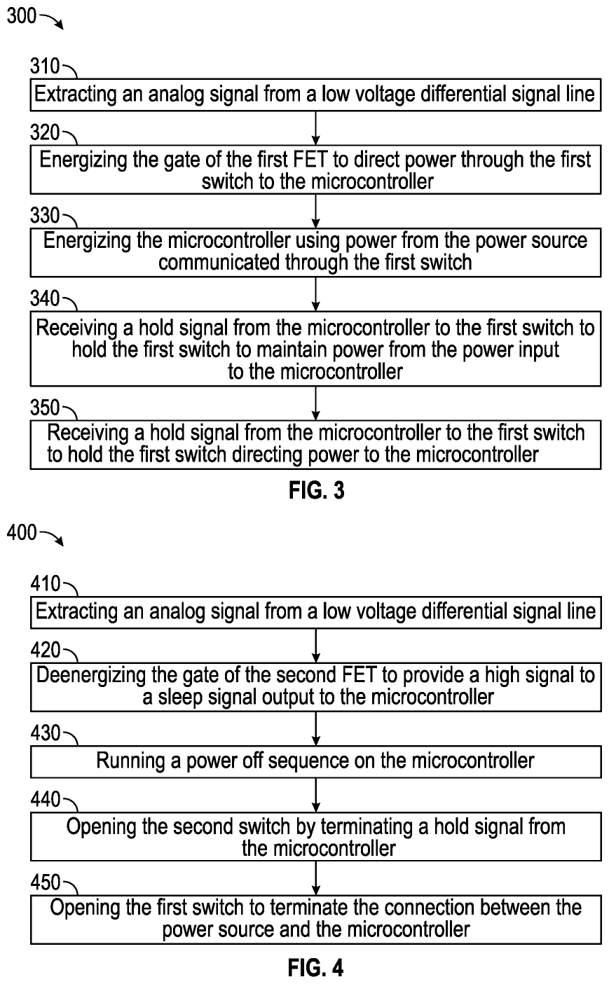

FIG. 1 shows a circuit diagram for an embodiment of a wake up apparatus 100. The apparatus 100 includes a set of field effect transistors (FETs) 110, 150 in a specific arrangement with a first switch 120 in communication with an input 115 for an electrical power source (i.e., a battery) 250 (see FIG. 2) to control a voltage output 125, and a second switch 130 controlled by a holding voltage 135. In some embodiments, the first switch 120 and the second switch 130 may be bipolar junction transistors or MOSFETs The first switch 120 may be realized as a MOSFET, and the second switch 130 may be realized by a BJT as shown in FIG. 1.

In one arrangement, the analog wake up signal superimposed on a low voltage differential signal (LVDS) line 260 may be received at an input 105 that is connected to the gates of a first FET 110 and a second FET 150, thus wake up voltage detection is performed by the two FETs 110, 150. The voltage levels for wake-up and sleep may be adjusted using a voltage divider circuit. A narrow threshold voltage range of the first FET 110 and the second FET 150 can be selected to achieve more precise and reliable control of the wake up and sleep activations. Each of the sources of the FETs 110, 150 is grounded. The drain of the first FET 110 is connected to and controls a power switch 120 that, in one position, connects electric power from the electrical power source input 115 to the voltage output 125. The power source input 115 may be divided (resistors R1, R2) prior to connection to the gate of the first switch 120, when the first switch 120 is in a closed state. The voltage output 125 powers a subsystem 210 that is being wakened by the apparatus 100. The subsystem may include processor, such as a microcontroller. The drain of the first FET 110 is also connected to the second switch 130 which is controlled by a hold voltage 135 input from the processor being wakened by the apparatus 100. The other pole of the second switch 130 is grounded. The drain of the second FET 150 is connected to a sleep signal output 155 and to a voltage source 140 with a pullup resistor 145 acting to pull the voltage up. The second switch 130 may be configured to keep the divided battery voltage from reaching the subsystem 210 (see FIG. 2). The second switch 130 is configured to remain open until a high voltage is provided at the HOLD voltage 135. The second switch 130 is configured to close when the Hold voltage 135 goes high. The closing of the second switch 130 connects the drain line of the first FET 110 to ground and holds the first switch 120 in a closed state. The first FET 110 may be selected with a specified gate voltage threshold, such as 2 volts. While exemplary and illustrative voltages are given here for clarity, any voltages may be used so long as the wake up voltage and the sleep voltage are distinct. In some embodiments, the wake up signal is 3.17 volts or higher. The second FET 150 may be selected with a gate voltage threshold so as to turn off when the signal received at the input 105 is below 1.8 volts (e.g., a sleep signal). In some embodiments, the sleep signal is triggered by a signal at the input 105 that is 1.26 volts or below. Both the first FET 110 and the second FET 150 may have the same gate threshold voltage (i.e., 2 volts). The first FET 110 and the second FET 150 are configured so that they are on when the input 105 is greater than 2 volts. The first FET 110 is configured to turn on the first switch 120 allowing power to flow from the power source input 115 to the voltage output 125, such that the subsystem 210 receives power. The voltage source 140 may be powered by the power source input 115 or other power source derived from the vehicle battery. Selection of the first FET 110 and the second FET 150 with specific gate voltage threshold may be used to position the voltage level for the wake/sleep states between designed wake and sleep command voltage levels. The gate voltage threshold may be selected to be approximately the middle of the range between the designed wake up signal voltage and the designed sleep signal voltage in order to minimize the risk of signal fluctuations causing the system to unintentionally wake up or go to sleep or oscillate between wake and sleep commands. Herein, the selected gate voltage threshold of 2 V is exemplary and illustrative only, as the gate voltage threshold may be selected for the FETs 110, 150 to position the voltage level for wake/sleep states as desired.

FIG. 2 shows a diagram of the system 200 using the wake up apparatus 100. The subsystem (i.e., microcontroller) 210 is in electrical communication with the apparatus 100. The subsystem 210 has a voltage input 220 connected to receive power from the electrical power source output 125. The subsystem 210 has a voltage output 230 that may be connected to the hold input 135 such that the subsystem 210 can supply voltage to the apparatus 100 to secure the first switch 120 closed with an OR circuit. The subsystem 210 may also include sleep signal input 240 that is connected to the sleep output 155 of the apparatus 100. When wake-up signal is low (for example, 1.26V or lower), 1) a sleep output 155 communicates a high voltage and 2) the subsystem 210 receives this high voltage and is programmed to respond by shutting down. This shutdown cycle includes storing of data into memory, thus avoiding memory loss due to an abrupt termination of power.

FIG. 3 shows a flow chart of a method 300 for the operation of the system 200 to wake up the microcontroller 210. In step 310, an analog control signal is transmitted on the LVDS 260, extracted, and received at the wake up input 105. In step 320, when the wake up signal is sufficient (for example, 3 volts or more), the voltage on the gate of the first FET 110 is sufficient so that the drain of the first FET 110 will provide sufficient voltage to close the first switch 120 between the power source input 115 and the electrical power output 125. In step 330, when the first switch 120 is energized, electrical power available at the electrical power source input 115 from the electrical power source 250 will flow through the first switch 120 to the electrical power output 125 and energize the subsystem 210 via the processor power input 220. In step 340, the processor 210 can then power up and will provide a holding voltage via the holding voltage output 230, which is connected to the holding voltage input 135. The voltage on the holding voltage input 135 closes the second switch 130 and allows the received holding voltage to keep the first switch 120 closed even if the wake up signal becomes momentarily insufficient due to noise. Thus, power is maintained to the processor 210 unless a sleep signal is received, at which point the processor releases the hold signal after completing a shutdown sequence.

FIG. 4 shows a flow chart of a method 400 for the operation of system 200 to be put into sleep mode after having been awake. Sleep mode may be induced by lowering the analog voltage below a selected threshold intentionally or due to a voltage drop, such as failing or weakening power source 250. In step 410, the analog control signal transmitted on the LVDS 260 or power signal on the LVDS 260 drops below a selected threshold (such as about 2 volts). In step 420, the drop in voltage below the selected threshold causes the first FET 110 and the second FET 150 to turn off. In step 430, the turning off of the second FET 150 causes the sleep signal output 155 to become high due to being pulled up by the voltage source 140. In step 430, the processor 210 detects the high voltage at the sleep signal output 155 as the sleep command-when it is received at the sleep voltage input 240 of the processor 210, and it triggers the sleep cycle of the processor 210. The processor 210 will then begin a shutdown process, which may include storing data to memory. In step 440, once the processor 210 has completed its preparatory steps for shutdown, the processor will decrease voltage on the holding voltage output 230 to the point where the second switch 130 will open, terminating the holding voltage supplied to the first switch 120. In step 450, the first switch 120 opens due to the absence of the holding voltage and breaks the connection from the power supply input 115 and the power supply output 125 and depowers the processor 210.

While embodiments in the present disclosure have been described in some detail, according to the preferred embodiments illustrated above, it is not meant to be limiting to modifications such as would be obvious to those skilled in the art.

The foregoing disclosure and description of the disclosure are illustrative and explanatory thereof, and various changes in the details of the illustrated apparatus and system, and the construction and the method of operation may be made without departing from the spirit of the disclosure.

What is claimed is:

1. An apparatus comprising:
an input line configured to receive a signal from a low voltage differential signal line;
a first field effect transistor (FET) with a gate in electrical communication with the input line;
a first switch configured to be controlled by a source of the first FET;
a power input in electrical communication with a first side of the first switch;
a power output in electrical communication with a second side of the first switch;
a second switch with a first side in electrical communication with the source of the first FET and configured to receive a hold control signal; and
a second FET with a gate in electrical communication with the input line and a drain in electrical communication with a pullup resistor and a sleep signal output.

2. The apparatus of claim 1, wherein the first switch comprises a MOSFET and the second switch comprises a BJT.

3. The apparatus of claim 1, further comprising:
a power source in electrical communication with the power input.

4. The apparatus of claim 1, further comprising:
a microcontroller configured to (1) receive power through the power output, (2) output the hold control signal, and (3) receive a sleep signal from the sleep signal output.

5. The apparatus of claim 1, wherein the first FET and the second FET are selected with a gate voltage threshold in the range of 1.26 volts and 3.17 volts.

6. A method of waking up a microcontroller in an apparatus comprising:
an input line configured to receive a signal from a low voltage differential signal line;
a first field effect transistor (FET) with a gate in electrical communication with the input line;
a first switch configured to be controlled by a drain of the first FET;
a power input in electrical communication with a first side of the first switch;
a power source in electrical communication with the power input;
a power output in electrical communication with a second side of the first switch;
a second switch with a first side in electrical communication with the drain of the first FET and configured to receive a hold control signal;
a second FET with a gate in electrical communication with the input line and a source in in electrical communication with a pullup resistor and a sleep signal output; and
a microcontroller configured to (1) receive power through the power output, (2) output the hold control signal, and (3) receive a sleep signal from the sleep signal output; and
comprising the steps of:
extracting an analog signal from the low voltage differential signal line;
energizing the gate of the first FET to connect the power input to the power output through the first switch;
energizing the microcontroller using power from the power source communicated through the first switch; and
receiving a hold signal from the microcontroller to the first switch to maintain the first switch connecting the power input to the power output.

7. A method of shutting down a microcontroller in an apparatus comprising:
an input line configured to receive a signal from a low voltage differential signal line;
a first field effect transistor (FET) with a gate in electrical communication with the input line;
a first switch configured to be controlled by a drain of the first FET;
a power input in electrical communication with a first side of the first switch;
a power source in electrical communication with the power input;
a power output in electrical communication with a second side of the first switch;
a second switch with a first side in electrical communication with the drain of the first FET and configured to receive a hold control signal;
a second FET with a gate in electrical communication with the input line and a drain in in electrical communication with a pullup resistor and a sleep signal output; and
a microcontroller configured to (1) receive power through the power output, (2) output the hold control signal, and (3) receive a sleep signal from the sleep signal output; and
comprising the steps of:
extracting an analog signal from the low voltage differential single line;
deenergizing the gate of the second FET to energize the sleep signal output;
running a power off sequence on the microcontroller; and
initiating a signal to open the second switch which opens the first switch and terminates power to the microcontroller.
